(19) United States
(12) Patent Application Publication
(10) Pub. No.: US 2006/0256523 A1
(43) Pub. Date: Nov. 16, 2006

(54) Fan and heat sink combination

(76) Inventor: Christian L. Belady, McKinney, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/126,665

(22) Filed: May 11, 2005

(51) Int. Cl. H05K 7/20

(52) U.S. Cl. 361/695

(57) ABSTRACT

A fan and heat sink combination for transferring heat from a heat source includes a base, a fan and a plurality of heat dissipation fins. The base is for conducting heat from the heat source. The fan is mounted on top of the base. The heat dissipation fins extend around the fan from the base to a location beyond a surface of the fan.

### BACKGROUND

Heat generated by components within electronic devices/systems, such as computer systems, etc., must be transferred away from the components in order to ensure proper and efficient operation of these components. As the electronic systems and/or components become faster, smaller, more densely packed and/or more powerful, the amount or density of heat generated by the various components becomes greater. Likewise, the difficulty encountered in dissipating the heat from these components within the confines of the systems becomes greater. Consequently, electronic systems makers continue to pursue heat transfer technology or devices capable of satisfying the increased heat transfer requirements of new components and/or new systems.

### BRIEF DESCRIPTION OF THE DRAWINGS

FIG. 1 is a top, front, left side perspective view of a computer system incorporating an embodiment of the present invention.

FIG. 2 is a top, side perspective view of a fan and heat sink combination for use in a system, such as the computer system shown in FIG. 1, and incorporating an embodiment of the present invention.

FIG. 3 is an exploded top, side perspective view of a fan and heat sink combination for use in a system, such as the computer system shown in FIG. 1, and incorporating an embodiment of the present invention.

FIG. 4 is a side cross sectional view of a fan and heat sink combination for use in a system, such as the computer system shown in FIG. 1, and incorporating an embodiment of the present invention.

FIG. 5 is a side cross sectional view of another fan and heat sink combination for use in a system, such as the computer system shown in FIG. 1, and incorporating an alternative embodiment of the present invention.

### DETAILED DESCRIPTION

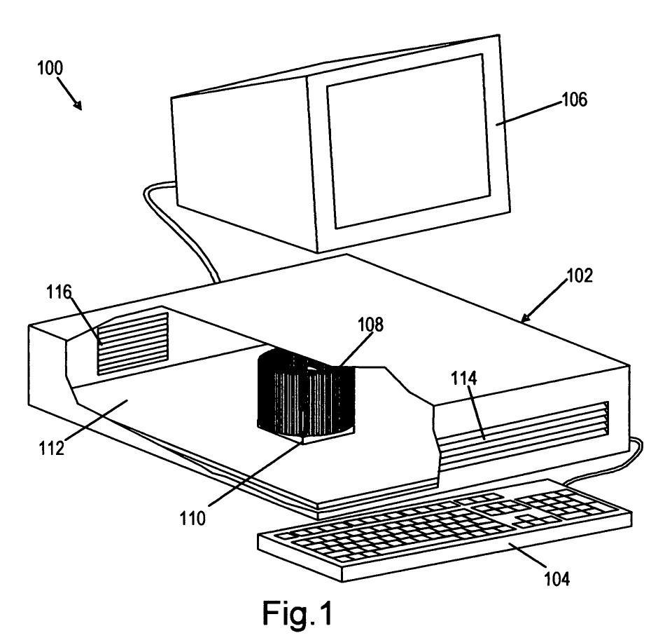

A computer system 100 incorporating an embodiment of the present invention is shown in FIG. 1 having elements such as a housing 102, a keyboard 104 and a display 106. A fan and heat sink combination 108, incorporating a first embodiment for transferring heat away from a component 110 of the computer system 100, is disposed at an appropriate location within the housing 102. The fan and heat sink combination 108 may be referred to as a “fan sink,” which is a term used in the art. The component 110 is an electrical heat generating component or other appropriate heat source, such as a processor, an IC (Integrated Circuit), an ASIC (Application Specific IC), a power supply, a hard drive, etc. The component 110 is typically mounted on a printed circuit board 112 within the housing 102. Vents 114 and 116 in the front and rear of the housing 102 permit air to flow into and out of the housing 102 to cool the fan and heat sink combination 108. Although one embodiment is described with respect to its use in the computer system 100 and the fan and heat sink combination 108, exemplary embodiments in accordance with the present invention can be used in any appropriate electronic system or assembly that includes a heat source with appropriate heat dissipation requirements, regardless of any other elements or components included in the electronic system.

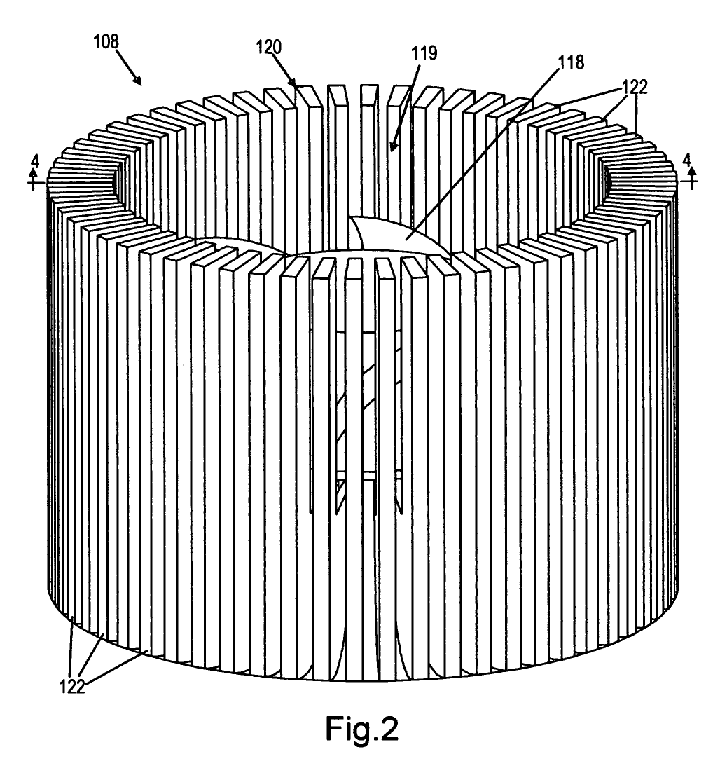

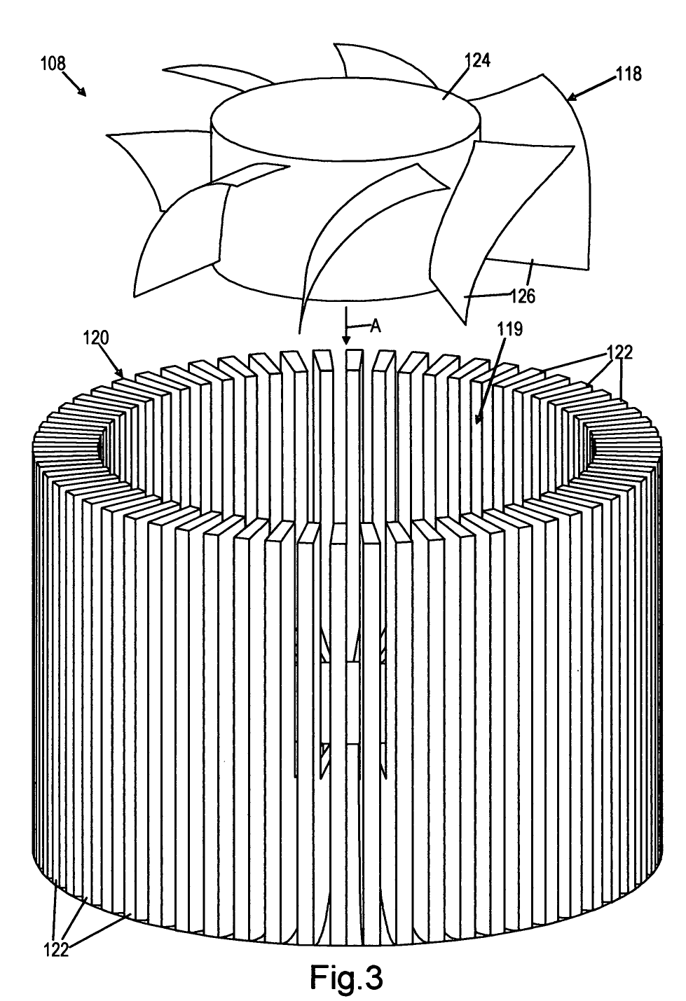

The fan and heat sink combination 108, as shown in FIGS. 2 and 3, generally includes a fan 118 mounted within a cavity 119 in a heat sink 120. The heat sink 120 generally includes multiple heat dissipation fins 122. According to the illustrated embodiment, the heat dissipation fins 122 are arranged in a generally circular pattern with a radial dimension. Other embodiments, however, may have other patterns, dimensions or shapes as appropriate for a given situation.

The fan 118 generally includes a motor 124 and multiple fan blades 126. The fan 118 is set into (e.g. in the direction of arrow A, FIG. 3) and surrounded by the heat dissipation fins 122. Additionally, the tops of the heat dissipation fins 122 extend substantially above the top of the fan 118 when the fan 118 is mounted within the heat sink 120, as shown in FIG. 2.

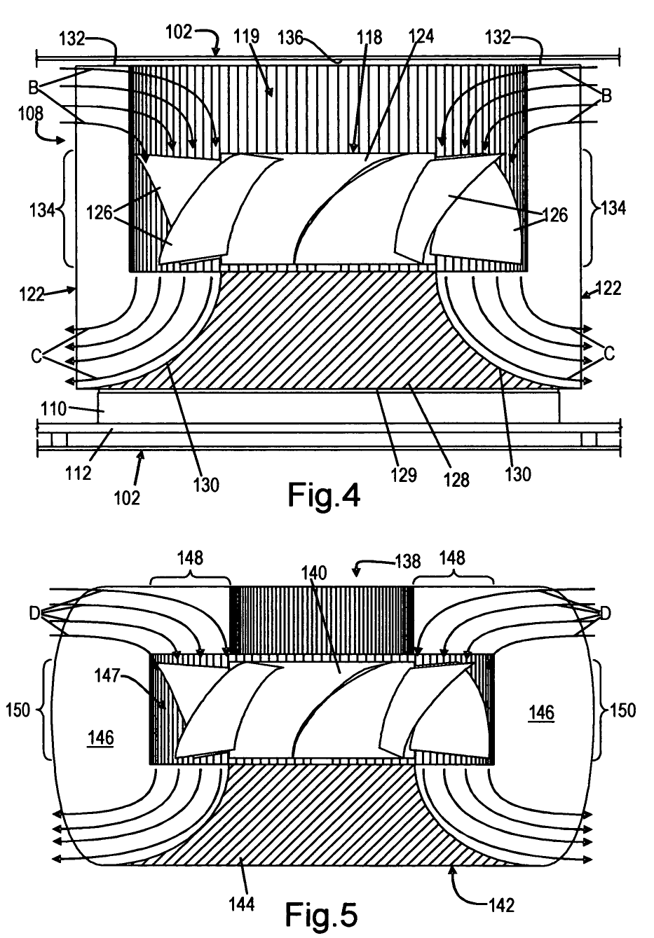

The heat sink 120 also generally includes a base 128, as shown in FIG. 4. The fan 118 is mounted on the top of the base 128. The heat dissipation fins 122 extend from a sloped or curved side of the base 128. The base 128 is mounted to the component 110 with a thermal interface material 129 in between. The base 128 may be a solid piece of thermally conductive material or may incorporate other heat transfer devices, such as vapor chambers, heat pipes, etc. Additionally, although the base 128 is shown as having a generally trapezoidal cross section with a concave curvature of the sloped sides, it is understood that embodiments in accordance with the present invention are not so limited. Instead, the base 128 may have any appropriate shape.

Heat generated by the component 110 is transferred to the heat sink 120 at the base 128. The heat is conducted through the base 128 to the heat dissipation fins 122. The heat is conducted through the heat dissipation fins 122 from a proximal end 130 of the heat dissipation fins 122 at the base 128 to a distal end 132 beyond the fan 118.

The fan 118 draws air from inside the housing 102 between the heat dissipation fins 122 near the distal end 132 and pushes the air between the heat dissipation fins 122 near the proximal end 130. Thus, the air generally flows in the direction of arrows B and C through the heat dissipation fins 122. The fan and heat sink combination 108 is a “two-pass counter-flow fan sink” since the airflow passes between the heat dissipation fins 122 twice and in the opposite direction to the flow of the heat conduction through the heat dissipation fins 122. A smaller amount of the air flows through the heat dissipation fins 122 in the mid region 134 thereof. The air that moves passed the heat dissipation fins 122 receives the heat from the heat dissipation fins 122.

In one exemplary embodiment, the top of the heat sink 120 (i.e. the distal ends 132 of the heat dissipation fins 122) is positioned adjacent or close to a surface 136, such as the top portion of the housing 102, as shown. In this situation, the airflow drawn by the fan 118 in to the interior of the heat sink 120 is ducted by the surface 136 through the heat dissipation fins 122 near the distal ends 132 thereof because of the small plenum space between the heat sink 120 and the surface 136. Accordingly, the effectiveness of the fan and heat sink combination 108 is maximized since the air is forced to flow between the heat dissipation fins 122.

In one exemplary embodiment, the heat sink 120 is formed from a block of thermally conductive material that is repeatedly cut by a saw to form the heat dissipation fins 122. A radial saw, for instance, forms the curved sloped surface of the base 128 from which the heat dissipation fins 122 extend. Alternatively, the heat dissipation fins 122 are formed separately from the base 128 and then attached to the surface of the base 128, e.g. by solder, epoxy or other appropriate means. The curve of the sloped surface of the base 128 helps direct the flow of the air, but the sloped surface may have any appropriate shape. In one exemplary embodiment, the cavity in the heat sink 120 in which the fan 118 is mounted is formed by boring into the block of thermally conductive material, or the block of thermally conductive material is molded with the cavity already formed therein.

Another fan and heat sink combination 138, incorporating an alternative embodiment, is shown in FIG. 5. The fan and heat sink combination 138 generally includes a fan 140 (similar to the fan 118, above) and a heat sink 142. The heat sink 142 includes a base 144 and heat dissipation fins 146. The fan 140 is mounted on top of the base 144 in a cavity 147 among the heat dissipation fins 146. The heat dissipation fins 146 extend from a sloped side of the base 144. According to this embodiment, the heat dissipation fins 146 extend higher and at least partially over the fan 140, e.g. in regions 148. In this manner, the heat dissipation fins 146 have a larger heat-transfer area than do the heat dissipation fins 122, above. Additionally, the larger heat-transfer area of the heat dissipation fins 146 makes use of a larger amount of the airflow region, as indicated by the arrows D, than do the heat dissipation fins 122. Furthermore, regions 150 of the heat dissipation fins 146 are wider than the regions 134 of the heat dissipation fins 122 (FIG. 4) and allow a greater amount of heat to be conducted through the regions 150 of the heat dissipation fins 146. Since the fan 140 is at least partially covered by the heat dissipation fins 146, however, the heat dissipation fins 146 are attached to the base 144 (e.g. by solder or epoxy) after the fan 140 has been attached to the base 144.

I claim:

1. A fan and heat sink combination for transferring heat from a heat source comprising:
a base for conducting heat from the heat source;
a fan mounted on top of the base; and
a plurality of heat dissipation fins extending around the fan and from the base to a location beyond a surface of the fan.

2. A fan and heat sink combination as defined in claim 1 wherein, the fan pulls air passed a first portion of each heat dissipation fin and pushes the air passed a second portion of each heat dissipation fin.

3. A fan and heat sink combination as defined in claim 2 wherein, the first portion of the heat dissipation fins is on an opposite side of the fan from the base; and
the second portion of the heat dissipation fins is on a same side of the fan as the base.

4. A fan and heat sink combination as defined in claim 2 wherein, the air passes between the heat dissipation fins twice.

5. A fan and heat sink combination as defined in claim 1 wherein, the heat is transferred from the heat source through the base into the heat dissipation fins; and
the heat is transferred through the heat dissipation fins counter to an air flow moved by the fan.

6. A fan and heat sink combination as defined in claim 1 wherein, the plurality of heat dissipation fins extend to a location over the fan.

7. A computer system comprising:
a component that generates heat;
a heat sink mounted on top of the component and comprising a base that attaches to the component and a plurality of heat dissipation fins that extend upward from the base; and
a fan mounted within a cavity surrounded by the heat dissipation fins, a top of the fan being below a top of the heat dissipation fins.

8. A computer system as defined in claim 7 further comprising:
a housing within which the component, the heat sink and the fan are disposed, the housing having a top portion, and the top of the heat dissipation fins positioned adjacent the top portion of the housing.

9. A computer system as defined in claim 8 wherein, the fan generates an air flow that is ducted by the top portion of the housing to pass primarily between the heat dissipation fins near the top of the heat dissipation fins.

10. A computer system as defined in claim 7 wherein, the fan pulls air between the heat dissipation fins near the top of the heat dissipation fins and pushes the air between the heat dissipation fins near the base.

11. A computer system as defined in claim 7 wherein, the fan moves air, first, between the heat dissipation fins at a first location, second, out from between the heat dissipation fins and, third, between the heat dissipation fins at a second location.

12. A computer system as defined in claim 7 wherein, heat conducts from the component through the heat dissipation fins in a first direction; and
the fan generates an airflow through the heat sink in a second direction that is opposite the first direction.

13. A heat sink, comprising:
means for attaching to a heat source;
means for dissipating the heat, the heat dissipating means being in thermally conductive relationship with the heat source attaching means; and means for moving air between the heat dissipating means, the heat dissipating means at least partially surrounding and extending beyond the air moving means.

14. A heat sink as defined in claim 13 wherein, the air moving means moves the air, first, between the heat dissipating means at a first location, second, out from between the heat dissipating means and, third, between the heat dissipating means at a second location.

15. A heat sink as defined in claim 13 wherein, the heat dissipating means comprises multiple fin means for conducting the heat.

16. A method of cooling a source of heat in an electronic system comprising:
providing a heat sink assembly comprising a base, a fan mounted on top of the base, and a plurality of heat dissipation fins extending around the fan and from a proximal end at the base to a distal end beyond the fan from the base;
transferring the heat from the source of the heat through the base into the heat dissipation fins;
the fan drawing air between the heat dissipation fins at a location near the distal end to transfer a portion of the heat from the heat dissipation fins to the air; and
the fan flowing the air between the heat dissipation fins at a location near the proximal end to transfer another portion of the heat from the heat dissipation fins to the air.

17. A method as defined in claim 16 wherein,
the electronic system includes a housing with a portion adjacent the distal end of the heat dissipation fins and which ducts the air to flow between the heat dissipation fins near the distal end of the heat dissipation fins.
